(19) United States
(12) Patent Application Publication
(10) Pub. No.: US 2026/0362921 A1
(43) Pub. Date: Nov. 12, 2026

(54) DISPLAY PANEL AND DISPLAY APPARATUS

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Yanyang SHANG, Beijing (CN); Zhongman ZHAO, Beijing (CN); Fei FANG, Beijing (CN); Mingkun YANG, Beijing (CN); Zhen LIU, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 19/470,084

(22) PCT Filed: Oct. 21, 2024
(86) PCT No.: PCT/CN2024/126119

§ 371 Date: Sep. 29, 2025

(30) Foreign Application Priority Data
Nov. 15, 2023 (CN) 202311522887.6

(51) Int. Cl. H10K 59/131

(52) U.S. Cl. CPC H10K 59/131

(57) ABSTRACT

A display panel includes a base substrate, and pixel units, first, second and third data lines thereon. Each pixel unit includes one first sub-pixel, at least one second sub-pixel and one third sub-pixel. Each column of pixel units includes at least a first sub-column, a second sub-column and a third sub-column. In a same column of pixel units, a part of first and third sub-pixels are in a first sub-column therein, the other part of the first and third sub-pixels are in a third sub-column therein, and at least a part of second sub-pixels are in a second sub-column therein. In the same column of pixel units, the first sub-pixels are electrically connected to one first data line, the second sub-pixels are electrically connected to at least one second data line, and the third sub-pixels are electrically connected to one third data line.

### CROSS-REFERENCE TO RELATED APPLICATIONS

This application is a national phase entry under 35 USC 371 of International Patent Application No. PCT/CN2024/126119, filed on Oct. 21, 2024, which claims priority to Chinese Patent Application No. 202311522887.6, filed on Nov. 15, 2023, titled “DISPLAY PANEL AND DISPLAY APPARATUS,” which are incorporated herein by reference in their entirety.

### TECHNICAL FIELD

The content of the present disclosure relates to a display panel and a display apparatus.

### BACKGROUND

With the development of display technology, the demand for low-power consumption in display products has become increasingly urgent. Taking the active-matrix organic light-emitting diode (AMOLED) in an OLED (Organic Light-Emitting Diode) type display panel as an example, its display power consumption may be divided into backplane (BP) circuit power consumption and OLED light-emitting device power consumption, in which as the update of the materials of the light-emitting devices, the device power consumption has been decreasing year by year, while the proportion of BP circuit power consumption in the total power consumption has been continuously increasing. Therefore, it is necessary to focus on reducing the overall display power consumption by addressing the BP circuit power consumption.

### SUMMARY

The problem of how to reduce the source driving power consumption of a display panel is solved by utilizing one or more embodiments of the present disclosure.

In a first aspect, a display panel is provided, which includes a base substrate, a plurality of pixel units arranged in an array on the base substrate, and a plurality of first data lines, a plurality of second data lines and a plurality of third data lines that are disposed on the base substrate. Each of the pixel units includes one first sub-pixel, at least one second sub-pixel and one third sub-pixel; each column of pixel units includes at least a first sub-column, a second sub-column and a third sub-column that are arranged in sequence along a first direction perpendicular to an extension direction of each column of pixel units; in a same column of pixel units, a part of first sub-pixels and a part of third sub-pixels are located in a first sub-column of the same column of pixel units, another part of the first sub-pixels and another part of the third sub-pixels are located in a third sub-column of the same column of pixel units, and at least a part of second sub-pixels are located in a second sub-column of the same column of pixel units; and each column of pixel units corresponds to one of the first data lines, at least one of the second data lines and one of the third data lines; and in the same column of pixel units, the first sub-pixels are electrically connected to one of the first data lines, the second sub-pixels are electrically connected to at least one of the second data lines, and the third sub-pixels are electrically connected to one of the third data lines.

In a second aspect of the present disclosure, a display apparatus is provided, including the display panel provided in the above first aspect.

The foregoing description is merely an overview of the technical scheme of the present disclosure. To enable a clearer understanding of the technical means of the present disclosure, implementation may be carried out in accordance with the content of the specification. Furthermore, to make the aforementioned and other objectives, features, and advantages of the present disclosure more readily apparent and understandable, specific embodiments of the present disclosure are provided below.

### BRIEF DESCRIPTION OF THE DRAWINGS

FIG. 1A shows an SPR pixel arrangement of an AMOLED;

FIG. 1B shows a schematic diagram of source drive timing for the SPR pixel arrangement of FIG. 1A;

FIG. 2A shows a schematic diagram of an alternate arrangement in units of one first sub-pixel and one third sub-pixel in accordance with some embodiments of the present disclosure;

FIG. 2B shows a schematic diagram of a staggered arrangement in units of two first sub-pixels and two third sub-pixels in accordance with some embodiments of the present disclosure;

FIG. 2C shows a schematic diagram of a source driving timing sequence of sub-pixels in accordance with some embodiments of the present disclosure;

FIG. 3 shows a schematic diagram of a pixel arrangement in a case of a pixel unit including two second sub-pixels in accordance with some embodiments of the present disclosure;

FIG. 4A shows a schematic diagram of a pixel arrangement and winding compensation in accordance with Scheme 1 of some embodiments of the present disclosure;

FIG. 4B shows a schematic diagram of a circuit layout of Scheme 1;

FIG. 4C shows a schematic diagram of a first electrode trace of the red sub-pixel R1 in the first row in FIG. 4B;

FIG. 4D shows a schematic diagram of a first electrode trace of the red sub-pixel R2 in the second row in FIG. 4B;

FIG. 4E shows a schematic diagram of a third electrode trace of the blue sub-pixel B1 in the first row in FIG. 4B;

FIG. 4F shows a schematic diagram of a third electrode trace of the blue sub-pixel B2 in the first row in FIG. 4B;

FIG. 5A shows a schematic diagram of a pixel arrangement and winding compensation in accordance with Scheme 2 of some embodiments of the present disclosure;

FIG. 5B shows a schematic diagram of a circuit layout of Scheme 2;

FIG. 6A shows a schematic diagram of a pixel arrangement and winding compensation in accordance with Scheme 3 of some embodiments of the present disclosure;

FIG. 6B shows a schematic diagram of a circuit layout of Scheme 3;

FIG. 7A shows a schematic diagram of a pixel arrangement and winding compensation in accordance with Scheme 4 of some embodiments of the present disclosure; and

FIG. 7B shows a schematic diagram of a circuit layout of Scheme 4.

### DESCRIPTION OF THE REFERENCE SIGNS

10: Pixel unit; 11: First sub-pixel; 12: Second sub-pixel; 13: Third sub-pixel; L1: First sub-column; L2: Second sub-column; L3: Third sub-column; L4: Fourth sub-column; A1: First region; A2: Second region; SD: Source-Drain metal layer; DL1: First data line; DL2: Second data line; DL3: Third data line; VDD: Power signal line; Block: Pad; 20: First electrode; 21: Main body; 22: Conductive block; 23A: First electrode trace; 23B: Second electrode trace; 23C: Third electrode trace; R: Red sub-pixel; G: Green sub-pixel; B: Blue sub-pixel.

### DETAILED DESCRIPTION

The following will describe embodiments of the present disclosure with reference to the accompanying drawings. However, it should be understood that these descriptions are exemplary and are not intended to limit the scope of the present disclosure. Furthermore, descriptions of well-known structures and techniques are omitted in the following explanation to avoid unnecessarily obfuscating the concepts of the present disclosure.

The accompanying drawings show various structures in accordance with the embodiments of the present disclosure. These drawings are not drawn to scale, in which certain details are enlarged for the purpose of clear expression, and certain details may be omitted. The shapes of various regions and layers shown in the drawings, as well as their relative sizes and position relationships, are merely illustrative. Actual values may have deviations due to manufacturing tolerances or technical limitations, and furthermore, those skilled in the art may alternatively design regions/layers with different shapes, sizes, and relative positions according to practical requirements.

In the context of the present disclosure, when a layer/element is referred to as being “on/over/above” another layer/element, this layer/element may be directly located on the another layer/element, or intermediate layer(s)/element(s) may exist therebetween. In addition, if a layer/element is located “on/over/above” another layer/element in one orientation, then if the orientation is reversed, this layer/element may be located “beneath/under/below” the another layer/element.

In the context of the present disclosure, unless otherwise specified, a light exit side of a display panel is referred to as “top side” or “upper side,” and the opposite side is referred to as “bottom side” or “lower side” for the convenience of describing relative directions. Correspondingly, a direction from the bottom side to the top side is a thickness direction of the display panel, and a direction perpendicular to the thickness direction is “plane direction” or “extension direction” of the display panel. It should be understood that these directions are all relative directions rather than absolute directions.

Unless otherwise defined, technical terms or scientific terms used in the embodiments of the present disclosure shall be understood as ordinary meanings by a person of ordinary skill in the art to which the present disclosure pertains. The “first,” “second” and similar words used in the present disclosure are not intended to indicate any order, quantity or importance, but are merely used to distinguish different components. Likewise, words such as “one,” “a/an,” or “the/this/that” do not indicate a limitation of quantity, but rather signify the existence of at least one. The words such as “comprise” or “include” are intended to mean that an element or an object that precedes the words encompasses element(s) or object(s) listed after the term, along with their equivalents, without excluding other elements or objects. The terms such as “connect,” “couple” or similar words are not limited to physical or mechanical connections, but may include electrical connections, whether direct or indirect. The terms “upper,” “lower,” “left,” “right,” and the like are only used to indicate a relative positional relationship, and if an absolute position of a described object is changed, the relative positional relationship may also be changed accordingly.

To improve the service life of display panels and ensure the aperture ratio, current display panels, especially organic light-emitting diode (OLED) display panels, are increasingly adopting sub-pixel rendering (SPR) technology. That is, by using the sub-pixel borrowing principle, two sub-pixels of different colors in each pixel unit in the display panel are shared by a sub-pixel of another color. Taking the arrangement of RGB (red, green and blue) sub-pixels as an example, two green sub-pixels often share one red sub-pixel and one blue sub-pixel to form two pixel units, which may not only ensure the resolution while reducing the number of pixels in the pixel array, but also appropriately increase the areas of sub-pixels to increase the aperture ratio, effectively compensating for the partial picture loss caused by fewer sub-pixels, which is beneficial to improving the display effect and service life.

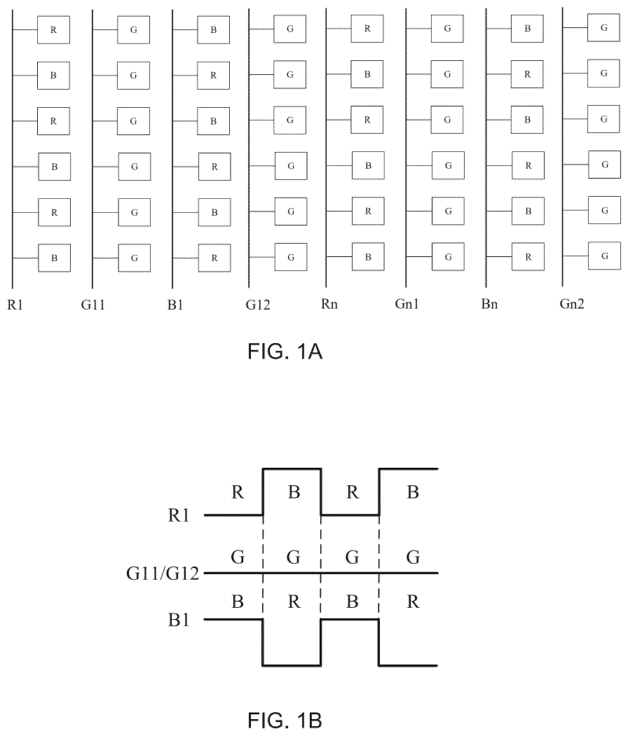

For example, an SPR pixel arrangement of an active matrix OLED (AMOLED) display panel may be seen in FIG. 1A, which adopts an RGBG pixel array arrangement scheme, that is, a pixel unit includes one red sub-pixel R, two green sub-pixels G and one blue sub-pixel B, and one green sub-pixel G can use a red sub-pixel R and a blue sub-pixel B surrounding it to form a light-emitting center. In some embodiments, each column of pixel units includes four columns of sub-pixels, in which red sub-pixels R and blue sub-pixels B are alternately arranged in the first column of sub-pixels and the third column of sub-pixels, and green sub-pixels G are arranged in the second column of sub-pixels and the fourth column of sub-pixels. The source driving of all columns of sub-pixels adopts the principle of proximity. For example, for the first column of pixel units, all red sub-pixels R and blue sub-pixels B in the first column of sub-pixels are connected to a data line R1 (Source Line) adjacent thereto, and all red sub-pixels R and blue sub-pixels B in the third column of sub-pixels are connected to a data line B1 adjacent thereto, all green sub-pixels G in the second column of sub-pixels are connected to a data line G11 adjacent thereto, and all green sub-pixels G in the fourth column of sub-pixels are connected to a data line G12 adjacent thereto; and so on, for the Nth column of pixel units, all red sub-pixels R and blue sub-pixels B in the first column of sub-pixels are connected to a data line Rn1 adjacent thereto, and all red sub-pixels R and blue sub-pixels B in the third column of sub-pixels are connected to a data line Bn1 adjacent thereto, all green sub-pixels G in the second column of sub-pixels are connected to a data line Gn1 adjacent thereto, and all green sub-pixels G in the fourth column of sub-pixels are connected to a data line Gn2 adjacent thereto.

However, this SPR pixel arrangement also brings about the problem of increased backplane (BP) circuit driving power consumption, specifically the source driving power consumption. The first column of sub-pixels and the second column of sub-pixels contain both red sub-pixels R and blue sub-pixels B, and the sub-pixels in each column share a same data line and are driven by pixel circuits in the same column. Therefore, when the display panel emits light, especially when the display panel displays a pure red or blue image, due to the principle of the intrinsic line-by-line activation of OLED, the driving voltages in the data line R1 and the data line B1 need to continuously jump manner, as shown in FIG. 1B. The driving voltages are provided by a source driving circuit (source-integrated circuit (S-IC)). The continuous jumping will significantly increase the source driving power consumption and reduce the endurance of the display panel.

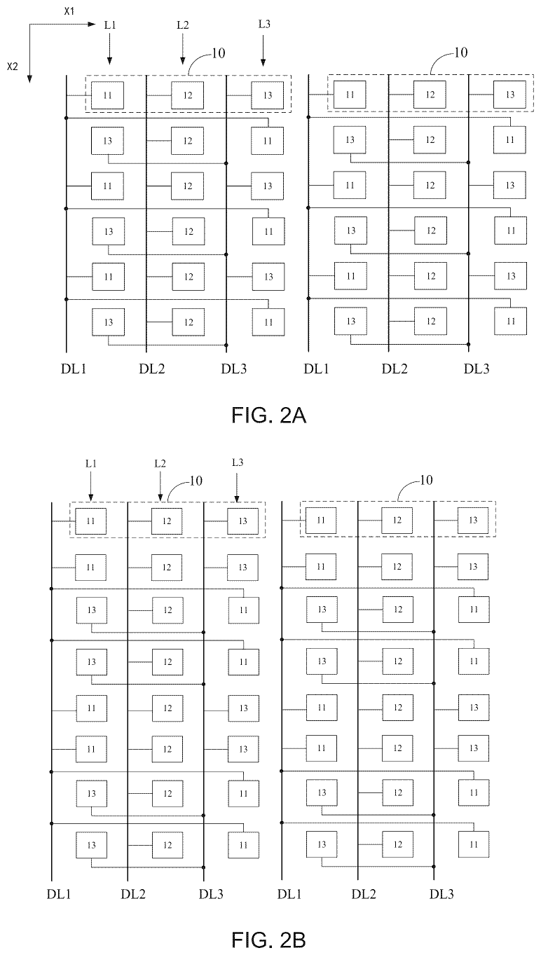

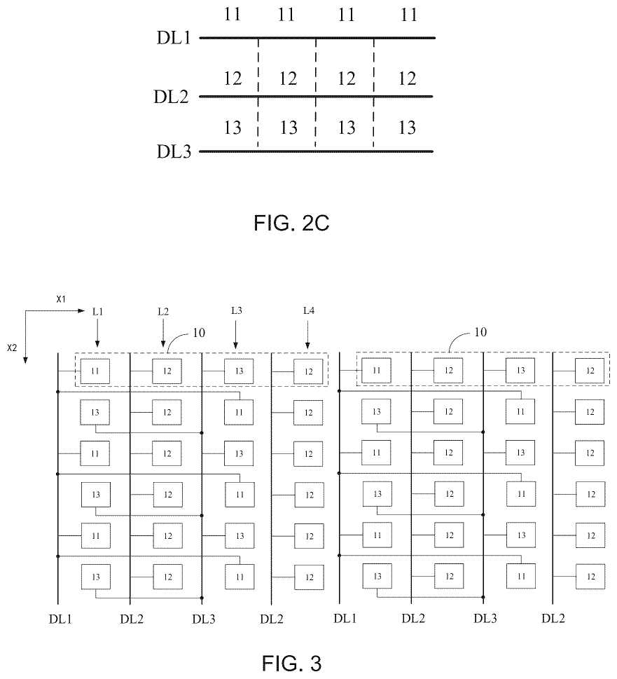

In light of this, in order to solve the problem of increased source driving power consumption, in the first aspect, in an optional embodiment, a display panel is provided, with a pixel arrangement shown in FIG. 2A. The display panel includes: a base substrate (not shown in the drawing) and a plurality of pixel units 10 arranged in an array on the base substrate.

Each pixel unit 10 includes a first sub-pixel 11, a second sub-pixel 12 and a third sub-pixel 13, and each column of pixel units 10 includes at least: a first sub-column L1, a second sub-column L2 and a third sub-column L3 arranged in sequence along the first direction X1. In a same column of pixel units 10, a part of first sub-pixels 11 and a part of third sub-pixels 13 are located in a first sub-column L1, the other part of the first sub-pixels 11 and the other part of the third sub-pixels 13 are located in a third sub-column L3, and second sub-pixels 12 are located in a second sub-column L2; each column of pixel units 10 corresponds to a first data line DL1, a second data line DL2 and a third data line DL3; and in the same column of pixel units 10, the first sub-pixels 11 are electrically connected to the first data line DL1, the second sub-pixels 12 are electrically connected to the second data line DL2, and the third sub-pixels 13 are electrically connected to the third data line DL3.

In some embodiments, the plurality of pixel units 10 arranged in an array form a pixel array, and each column includes multiple pixel units 10. The first direction X1 in the present disclosure is a row direction of the pixel array, and there is a second direction X2 intersecting the first direction X1, which is a column direction of the pixel array. The first sub-column L1, the second sub-column L2 and the third sub-column L3 are arranged in sequence in the first direction X1, that is, in the row direction of the pixel array, and sub-pixels contained in each sub-column are arranged in the second direction X2, that is, in the column direction of the pixel array. The first sub-pixel 11, the second sub-pixel 12, and the third sub-pixel 13 are sub-pixels of three different colors, such as the currently commonly used RGB sub-pixels. Unless otherwise specified, the embodiments of the present disclosure are described by taking the first sub-pixel 11 as a red sub-pixel R, the second sub-pixel 12 as a green sub-pixel G, and the third sub-pixel 13 as a blue sub-pixel B as an example.

Therefore, in the same column of pixel units 10, the first sub-column L1 and the third sub-column L3 are both provided with the first sub-pixels 11 and the third sub-pixels 13, and the second sub-column L2 is provided with only the second sub-pixel 12. In this way, an SPR pixel structure may be formed, in which each second sub-pixel 12 in the second sub-column L2 may use a first sub-pixel 11 and a third sub-pixel 13 adjacent thereto to form a light-emitting center, which is beneficial to reducing the number of sub-pixels and improving the aperture ratio and service life while ensuring the total pixel density.

In any one of the first sub-column L1 and the third sub-column L3, the first sub-pixels 11 and the third sub-pixels 13 may be arranged in sequence at intervals or alternately. Taking the first sub-pixel 11 as a red sub-pixel R and the third sub-pixel 13 as a blue sub-pixel B as an example, in the second direction X2, FIG. 2A adopts an alternate arrangement, that is, the first sub-column L1 in each column of pixel units 10 adopts an RBRBRB arrangement, and correspondingly, the third sub-column L3 corresponds to a BRBRBR arrangement to ensure the integrity of the pixel unit 10 in the first direction X1. In addition, a two-and-two staggered arrangement as shown in FIG. 2B may also be employed, that is, the first sub-column L1 adopts an RRBBRRBB sub-pixel arrangement, and the third sub-column L3 adopts a BBRRBBRR sub-pixel arrangement, which may also form a pixel borrowing structure.

Furthermore, the base substrate is provided thereon with first data lines DL1, second data lines DL2 and third data lines DL3 that are arranged along the first direction X1 and extend in the second direction X2. A range of a column of pixel units 10 at least encompasses one first data line DL1, one second data line DL2, and one third data line DL3. Unlike the current scheme in which sub-pixels of different colors in the same column are driven by the same data line adjacent thereto, in this scheme, the first sub-pixels 11 in the first sub-column L1 and the third sub-column L3 are connected to the first data line DL1, and the third sub-pixels 13 in the first sub-column L1 and the third sub-column L3 are connected to the third data line DL3. That is, sub-pixels of the same color located in different sub-columns are driven by the same data line, thereby adjusting driving signals of the first data line DL1 and the third data line DL3 to stable DC voltage driving, as shown in FIG. 2C, thereby reducing the power consumption loss of the source driving caused by the voltage jumping.

Through simulation of the driving circuit, the results show that this design is expected to reduce the power consumption of the first sub-pixel 11/the third sub-pixel 13 by about 25% under pure color images, and may also reduce the power consumption for conventional color images.

For an OLED display panel, four sub-pixels may be used to form a light-emitting center to form one pixel unit 10. In some embodiments, referring to FIG. 3, a pixel unit 10 includes one first sub-pixel 11, two second sub-pixels 12 and one third sub-pixel 13, each column of pixel units 10 corresponds to one first data line DL1, two second data lines DL2 and one third data line DL3; each column of pixel units 10 further includes a fourth sub-column L4, and the third sub-column L3 is located between the second sub-column L2 and the fourth sub-column L4. In the same column of pixel units 10, second sub-pixels 12 are located in the second sub-column L2 and the fourth sub-column L4, second sub-pixels 12 in the second sub-column L2 are electrically connected to one second data line DL2, and second sub-pixels 12 in the fourth sub-column L4 are electrically connected to the other second data line DL2; in the first sub-column L1 and the third sub-column L3, first sub-pixels 11 and third sub-pixels 13 are alternately arranged, that is, the first sub-pixels 11 and the third sub-pixels 13 are alternately arranged; and in the first sub-column L1 and the third sub-column L3, a first sub-pixels 11 is flanked on both sides by third sub-pixels 13, and a third sub-pixel 13 is flanked on both sides by first sub-pixels 11.

For OLEDs, the first sub-pixel 11 may be a red sub-pixel R, the second sub-pixel 12 may be a green sub-pixel G, and the third sub-pixel 13 may be a blue sub-pixel B, thereby forming an SPR pixel arrangement of RGBG. It can be understood that the second sub-pixel 12 may be a sub-pixel of another color, capable of effectively forming pixel borrowing with the first sub-pixel 11 and the third sub-pixel 13 to produce white light.

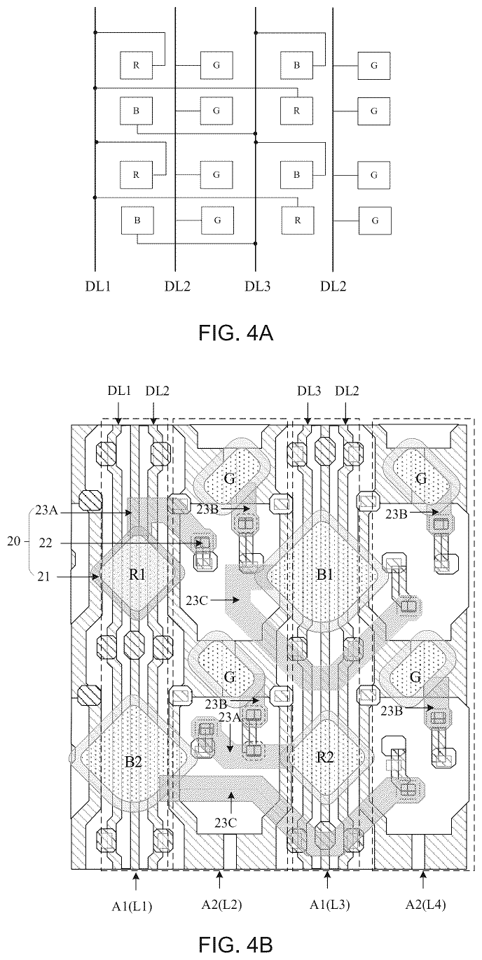

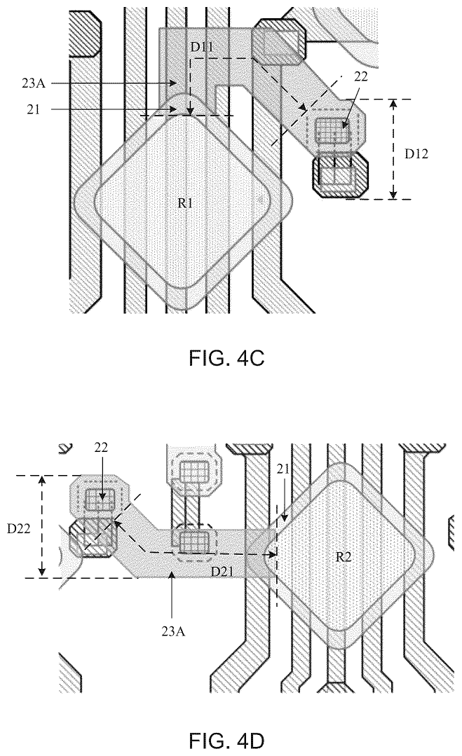

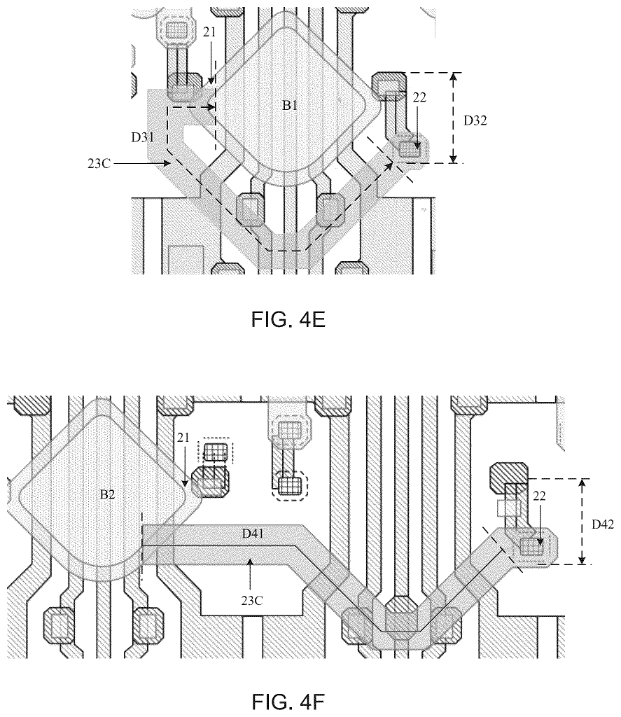

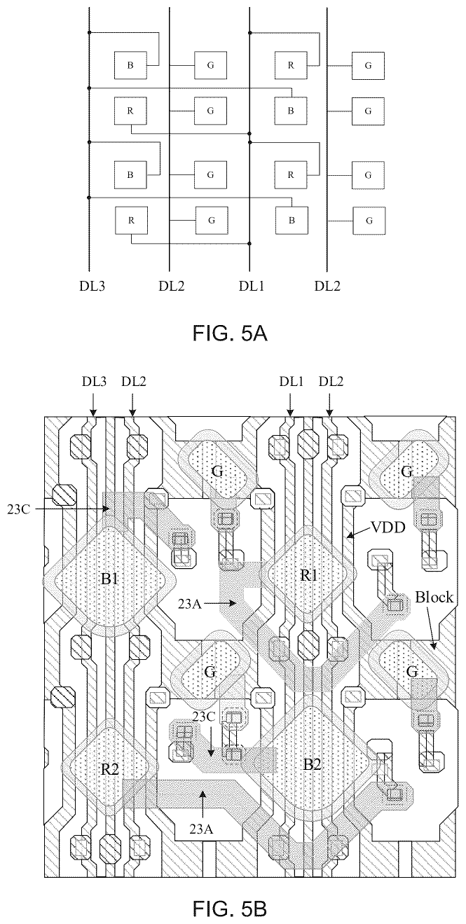

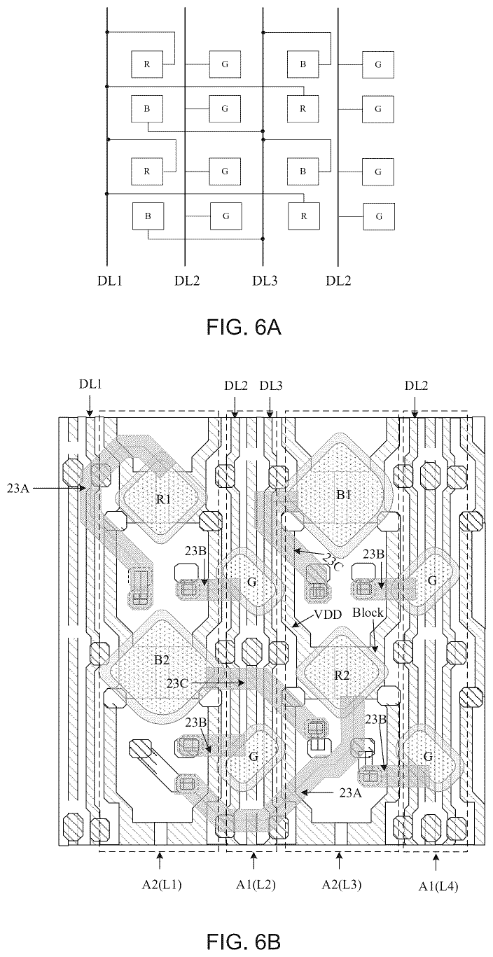

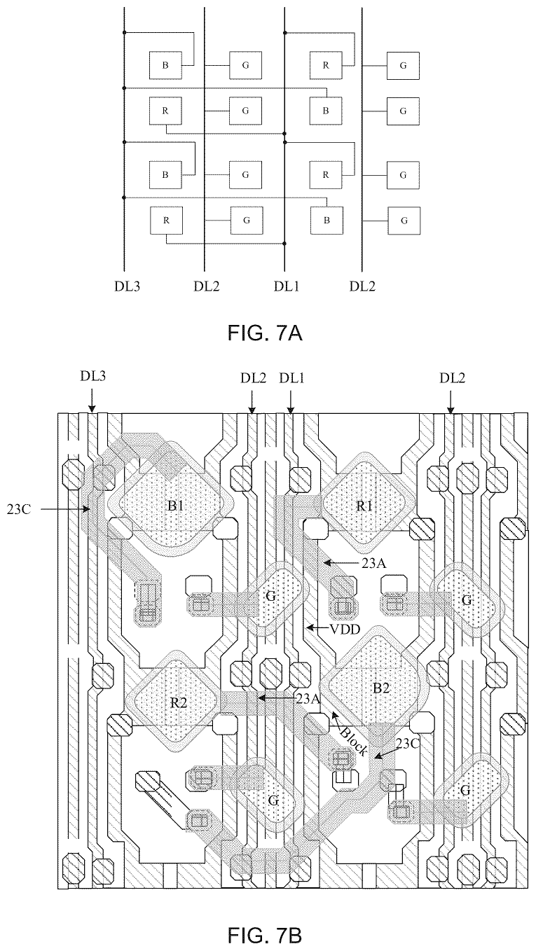

For OLEDs, in some embodiments, referring to FIG. 4B, FIG. 5B, FIG. 6B and FIG. 7B, each sub-pixel includes a first electrode 20 stacked on the base substrate; the first electrode 20 includes a main body 21 and a conductive block 22. For the first sub-pixel 11, a main body 21 is connected to a conductive block 22 through a first electrode trace 23A, and the conductive block 22 is connected to a first data line DL1; for the second sub-pixel 12, a main body 21 is connected to a conductive block 22 through a second electrode trace 23B, and the conductive block 22 is connected to a second data line DL2; and for the third sub-pixel 13, a main body 21 is connected to a conductive block 22 through a third electrode trace 23C, and the conductive block 22 is connected to a third data line DL3.

In some embodiments, stacked structures of the display panel may include a source-drain metal layer SD, a planarization layer (PLN), a pixel definition layer (PDL), and an electroluminescent device layer stacked in sequence. These stacked structures are described in detail below.

The source-drain metal layer SD is stacked on the base substrate. The first data lines DL1, the second data lines DL2 and the third data lines DL3 are disposed in the source-drain metal layer SD and extend along the second direction X2. The source-drain metal layer SD may be a multi-layer structure, such as a 2SD or 3SD structure. Taking 3SD as an example, the source-drain metal layer SD includes a first trace layer (SD1), a second trace layer (SD2) and a third trace layer (SD3) from proximate to away from the base substrate, in which the SD1 layer mainly serves as sources and drains of transistors in pixel driving circuits, as well as other connecting lines; the main function of the SD2 layer is to switch and connect the signal lines, and the SD3 layer is used to provide the first data lines DL1, the second data lines DL2 and the third data lines DL3. In addition, the SD3 layer may further provide power signal lines VDD for transmitting a VDD signal. If the source-drain metal layer SD is a 2SD structure, the first data lines DL1, the second data lines DL2 and the third data lines DL3 may be disposed in the SD2 layer.

The planarization layer is stacked on the source-drain metal layer SD and plays the role of planarization and insulation.

The pixel definition layer (PDL) is arranged on a side of the planarization layer away from the base substrate, and the pixel definition layer includes: pixel openings for defining light-emitting regions of the first sub-pixels 11, light-emitting regions of the second sub-pixels 12, and light-emitting regions of the third sub-pixels 13.

For the electroluminescent device layer, each sub-pixel includes an electroluminescent device, which includes at least the first electrode 20, a light-emitting layer and a second electrode. The first electrode 20 is closer to the base substrate than the second electrode, that is, the first electrode 20 is located on a side of the light-emitting layer proximate to the base substrate. The first electrode 20 may be an anode or a cathode of the electroluminescent device, and the second electrode is the other electrode of the anode and the cathode. Unless otherwise specified, the present disclosure is described with the first electrode 20 as an anode.

The main body 21 in the first electrode 20 is a main electrode portion of the electroluminescent device, and the conductive block 22 is a connecting structure connected to a corresponding data line. In some embodiments, PLN holes are provided in the planarization layer, and the conductive block 22 may be connected to the SD2 layer through a PLN hole, and then connected to the corresponding data line through the SD1 layer.

The pixel opening of the pixel definition layer exposes at least a portion of the main body 21. For example, an orthographic projection of a portion of the main body 21 on the base substrate overlaps with an orthographic projection of the pixel opening on the base substrate, while an orthographic projection of the other portion on the base substrate does not overlap the orthographic projection of the pixel opening on the base substrate; for another example, an orthographic projection of the main body 21 on the base substrate is located within the orthographic projection of the pixel opening on the base substrate. Optionally, the main body 21 has a shape consistent with that of the corresponding pixel opening, and an edge of the main body 21 aligns directly with an edge of the corresponding pixel opening after the corresponding pixel opening expands outward by one circle. The first electrode trace 23A is connected to a main body 21 and a conductive block 22 corresponding to the first sub-pixel 11, the second electrode trace 23B is connected to a main body 21 and a conductive block 22 corresponding to the second sub-pixel 12, and the third electrode trace 23C is connected to a main body 21 and a conductive block 22 corresponding to the third sub-pixel 13. In a case where the first electrode 20 is an anode, the first electrode trace 23A, the second electrode trace 23B, and the third electrode trace 23C may also be referred to as anode traces.

In some embodiments, in the same column of pixel units 10, for a first sub-pixel 11 proximate to the first data line DL1, a first electrode trace 23A is connected to a conductive block 22 and an end of a main body 21 away from the first data line DL1; for a first sub-pixel 11 away from the first data line DL1, a first electrode trace 23A is connected to a conductive block 22 and an end of a main body 21 proximate to the first data line DL1. The same applies to the third sub-pixels 13, for a third sub-pixel 13 proximate to the third data line DL3, a third electrode trace 23C is connected to an end of a main body 21 away from the third data line DL3; for a third sub-pixel 13 away from the third data line DL3, a third electrode trace 23C is connected to an end of a main body 21 proximate to the third data line DL3.

In some embodiments, the first sub-pixels 11 are distributed in both the first sub-column L1 and the third sub-column L3, and the first data line DL1 is usually proximate to the first sub-column L1 or the third sub-column L3, therefore sub-pixels of one of the first sub-column L1 and the third sub-column L3 will inevitably be away from the first data line DL1, resulting in the first sub-pixels 11 away from the first data line DL1 having longer first electrode traces 23A. The longer first electrode traces 23A will increase resistance and capacitance (RC loading), causing uneven brightness of the first sub-pixels 11 in the first sub-row L1 and the third sub-row L3. Therefore, the above scheme is to perform winding compensation on the first electrode trace 23A of the first sub-pixel 11 proximate to the first data line DL1, by enabling the first electrode trace 23A corresponding to the first sub-pixel 11 proximate to the first data line DL1 to be connected to the end of the main body 21 away from the first data line DL1, thereby increasing the length of the first electrode trace 23A to balance the RC loading in the first sub-column L1 and the third sub-column L3.

To balance the RC loading, a deviation between sizes of a first electrode trace 23A of a first sub-pixel 11 proximate to the first data line DL1 and a first electrode trace 23A of a first sub-pixel 11 away from the first data line DL1 may be made not to exceed 10%, and the deviation between the sizes includes a deviation between lengths of the first electrode traces 23A or a deviation between areas of orthographic projections of the first electrode traces 23A on the base substrate. The same applies to the third electrode trace 23C. In this way, the anode traces with and without winding in odd and even rows have approximately equal lengths or areas to ensure the consistency of resistance and the consistency of capacitance. The preferred approach is to make the lengths or areas of both as close or equal as possible.

In some embodiments, an optional winding compensation method is: in the same column of pixel units 10, for a first sub-pixel 11 proximate to the first data line DL1, a corresponding first electrode trace 23A at least partially surrounds a main body 21 and is connected to a conductive block 22. Similarly, for a third sub-pixel 13 proximate to the third data line DL3, a corresponding third electrode trace 23C at least partially surrounds a main body 21 and is connected to a conductive block 22.

Here, partially surrounding means that the first electrode trace 23A or the third electrode trace 23C surrounds a portion of an edge of the main body 21 for wiring, rather than surrounding the entire periphery of the main body 21. For example, in some embodiments, the main body 21 is in a shape of a right-angled rectangle or a rounded rectangle, and the rectangular main body 21 includes a first edge, a second edge, a third edge and a fourth edge, the first edge and the third edge are one group of opposite edges, and the second edge and the fourth edge are another group of opposite edges; the first electrode trace 23A includes a first connecting portion, a first connecting line, a second connecting line, and a second connecting portion that are connected to each other, the first connecting portion is connected the main body 21, the first connecting line is parallel or approximatively parallel to the first edge, the second connecting line is parallel or approximatively parallel to the second edge, and the second connecting portion is connected to the conductive block 22. In some embodiments, the main body 21 may also be in a shape of a circle or an ellipse, and the first electrode trace 23A or the second electrode trace 23B may surround ¼ or ½ of the circumference for wiring.

In some embodiments, referring to FIG. 4B, FIG. 5B, FIG. 6B and FIG. 7B, the source-drain metal layer SD further includes a plurality of power signal lines VDD extending along the second direction X2 and pads Block connected to the power signal lines VDD; the pads are formed by making large-area blocks of the source-drain metal layer SD, which may flatten the sub-pixels and improve the uniformity of light emission.

In order to more intuitively illustrate the SPR sub-pixel arrangement and corresponding winding design of the present invention, in the following embodiments, the first electrode 20 is used as the anode, the first sub-pixel 11 is the red sub-pixel R, the second sub-pixel 12 is the green sub-pixel G, and the third sub-pixel 13 is the blue sub-pixel B as an example for explanation, and for the convenience of description, orthographic projections of first electrodes 20 of the red sub-pixel R and the blue sub-pixel B on the source-drain metal layer SD is referred to as a first orthographic projection, and an orthographic projection of a first electrode 20 of the green sub-pixel G on the source-drain metal layer SD is referred to as a second orthographic projection.

Scheme 1: referring to FIG. 4A and FIG. 4B, the red sub-pixels R and the blue sub-pixels B are disposed at the data lines, and the green sub-pixels G are disposed at the pads Block. In this case, at least two of the first data line DL1, the second data line DL2 and the third data line DL3 pass through the first orthographic projection, and the second orthographic projection at least partially overlaps with the pad Block.

In some embodiments, in the pixel arrangement of FIG. 4A, in the first row, a red sub-pixel R in the first sub-column L1 is proximate to the first data line DL1 connected thereto, and a blue sub-pixel B in the third sub-column L3 is proximate to the third data line DL3 connected thereto; in the second row, a blue sub-pixel B in the first sub-column L1 is away from the third data line DL3 connected thereto, and a red sub-pixel R in the third sub-column L3 is away from the first data line DL1 connected thereto. Therefore, for the first sub-column L1, a first electrode trace 23A corresponding to the red sub-pixel R in the first row is wound, and for the third sub-column L3, a first electrode trace 23A of the red sub-pixel R in the second row is disposed normally, and similarly for subsequent rows; the same applies to the blue sub-pixels B, a third electrode trace 23C corresponding to the blue sub-pixel B in the first row is wound, and a third electrode trace 23C of the blue sub-pixel B in the second row is disposed normally, and similarly for subsequent rows.

In the circuit layout of FIG. 4B, the red sub-pixels R and the blue sub-pixels B are located above the data line, and the green sub-pixels G are located above the pads Block. In the first row, a red sub-pixel R1 is proximate to the first data line DL1, and a blue sub-pixel B1 is proximate to the third data line DL3; and in the second row, a red sub-pixel R2 is away from the first data line DL1, and a blue sub-pixel B2 is away from the third data line DL3. Therefore, during winding compensation, a first electrode trace 23A of the red sub-pixel R1 located in the first row partially surrounds a main body 21 of the red sub-pixel R1 and is then connected to a conductive block 22 thereof, and a third electrode trace 23C of the blue sub-pixel B1 located in the first row partially surrounds a main body 21 of the blue sub-pixel B1 and is then connected to a conductive block 22 thereof; and a red sub-pixel R2 located in the second row is directly connected to a conductive block 22 through a first electrode trace 23A, and the blue sub-pixel B2 is directly connected to a conductive block 22 through a third electrode trace 23C, without winding compensation.

Optionally, referring to FIG. 4B, the first data line DL1 and the second data line DL2 pass through a first orthographic projection at the first sub-column L1, and portions thereof within the first orthographic projection are symmetrically distributed; the third data line DL3 and the second data line DL2 pass through a first orthographic projection at the third sub-column L3, and portions thereof within the first orthographic projection are symmetrically distributed. Symmetrical distribution may be point symmetry or line symmetry, in which the point symmetry may be that the data lines are symmetrically distributed with respect to the center point of the first orthographic projection, and the line symmetry may be that the data lines are symmetrically distributed with respect to the axis of the first orthographic projection. The symmetrical distribution cooperates with the planarization layer to further improve the flatness of the first sub-pixel 11 and the third sub-pixel 13 and enhance the light emission uniformity.

To balance the RC loading of the anodes, this scheme is to keep the lengths of the wound anode traces and the unwound anode traces as consistent as possible.

FIG. 4C shows the length of the first electrode trace 23A, i.e., the length of the anode trace, corresponding to the red sub-pixel R1 in the first row, and the measured results are D11=20.8 μm and D12=11.9 μm. FIG. 4D shows the length of the first electrode trace 23A corresponding to the red sub-pixel R2 in the second row, and the measured results are D21=19.2 μm and D22=14 μm. FIG. 4E shows the length of the third electrode trace 23C corresponding to the blue sub-pixel B1 in the first row, and the measured results are D31=73.3 μm and D32=18.7 μm. FIG. 4F shows the length of the third electrode trace 23C corresponding to the blue sub-pixel B2 in the second row, and the measured results are D41=72.4 μm and D42=18.7 μm. It can be seen that the blue sub-pixel B has a longer anode trace than the red sub-pixel R.

The RC loading of the red sub-pixel R and the blue sub-pixel B has been tested, with the results shown in Table 1 below. It can be seen that a deviation of the RC Loading between the red sub-pixels R in two adjacent rows and a deviation of the RC Loading between the blue sub-pixels B in two adjacent rows are both within 2%, which shows good consistency.

Table 1: Values of the RC Loading of the red sub-pixels R and the blue sub-pixels B

| Sub-pixel | Resistor (Res)/Ω | Capacitor (Cap)/fF |
|---|---|---|
| Red sub-pixel R1 in | 0.36 | 20.778 |
| the first row | | |
| Red sub-pixel R2 in | 0.35 | 20.308 |
| the second row | | |
| Blue sub-pixel B1 in | 1.15 | 35.164 |
| the first row | | |
| Blue sub-pixel B2 in | 1.16 | 34.651 |
| the second row | | |

Through the above-mentioned anode winding design, the RC loading of the anodes of the red sub-pixels R and the blue sub-pixels B in odd and even rows is balanced while ensuring process capability, so that the brightness remains consistent when emitting light.

It will be noted that the pixel design in FIG. 4C to FIG. 4F is based on 460 PPI and a pixel pitch of 55.2 μm. The above data is only for exemplary purposes. Products with different PPIs may have anode traces with different line widths, different line spacings and different line lengths. The present disclosure does not specify particular parameters but only addresses the following: for pixels in odd and even rows with the same color, the line length of the anode trace and the underlying circuit overlap trace should be kept as consistent as possible, if process capability permits.

Scheme 2: referring to FIG. 5A and FIG. 5B, similar to Scheme 1, the red sub-pixels R and the blue sub-pixels B are arranged at the data line, and the green sub-pixels G are arranged at the pads block, and the difference is that the positions of the red sub-pixels R and the blue sub-pixels B in each row are inverse to those in Scheme 1, and the red sub-pixel R has a longer first electrode trace 23A relative to the blue sub-pixel B, i.e., the anode winding compensation. It can be understood that in a case where the red sub-pixels R in odd and even rows have the first electrode traces 23A of the equal or approximately equal length and the blue sub-pixels B have the third electrode traces 23C of the equal or approximately equal length, reversing their positions will not affect the balance of the RC loading.

Scheme 3: referring to FIG. 6A and FIG. 6B, the difference from Scheme 1 and Scheme 2 is that the red sub-pixels R and the blue sub-pixels B are arranged at the pads Block, and the green sub-pixels G are arranged at the data lines, that is, first orthographic projections of first electrodes 20 of the red sub-pixels R and the blue sub-pixels B on the source-drain metal layer SD at least partially overlap with the pads Block, and at least one of the first data line DL1, the second data line DL2 and the third data line DL3 passes through the second orthographic projections of first electrodes 20 of the green sub-pixels G on the source-drain metal layer SD. Furthermore, the red sub-pixel R has a longer first electrode trace 23A than the blue sub-pixel B, i.e., the length of the anode winding compensation is longer.

Optionally, referring to FIG. 6B, the second data line DL2 and the third data line DL3 pass through the second orthographic projection of the second sub-column L2, and portions thereof within the second orthographic projection are symmetrically distributed. The symmetrical distribution may be point symmetry or line symmetry, cooperating with the planarization layer to further improve the flatness of the second sub-pixel 12 to ensure uniform light emission.

Solution 4: referring to FIG. 7A and FIG. 7B, the same as Scheme 3 is that the red sub-pixels R and the blue sub-pixels B are arranged at the pads Block, and the green sub-pixels G are arranged at the data lines, and the difference from Scheme 3 is that positions of the red sub-pixels R and the blue sub-pixels B in each row are inverse to those in Scheme 3, and the blue sub-pixel B has a longer anode winding compensation relative to the red sub-pixel R.

In another aspect, referring to FIG. 4B and FIG. 6B, if on the source-drain metal layer SD, a region where the first data line DL1, the second data line DL2 and the third data line DL3 are located is regarded as a first region A1, and a region where the power signal line VDD and pads Block are located is regarded as a second region A2, first regions A1 and second regions A2 are alternately arranged in the first direction X1. Another description of the anode winding compensation may be as follows.

For Scheme 1 and Scheme 2, in a case where at least one of the first data line DL1, the second data line DL2 and the third data line DL3 passes through the first orthographic projection, that is, the red sub-pixel R and the blue sub-pixel B are located in the first region A1, for the first sub-pixel 11 away from the first data line DL1, the first electrode trace 23A crosses adjacent second regions A2 and is connected to the conductive block 22; for the first sub-pixel 11 proximate to the first data line DL1, the first electrode trace 23A at least partially surrounds the main body 21 and is connected to the conductive block 22.

For Scheme 3 and Scheme 4, in a case where the first orthographic projection at least partially overlaps with the pad Block, that is, the red sub-pixel R and the blue sub-pixel B are located in the second region A2, for the first sub-pixel 11 away from the first data line DL1, the first electrode trace 23A crosses adjacent first regions A1 and is connected to the conductive block 22; for the first sub-pixel 11 proximate to the first data line DL1, the first electrode trace 23A at least partially surrounds the main body 21 and is connected to the conductive block 22.

In summary, the above-mentioned SPR pixel arrangement combined with the anode compensation winding design not only reduces the source driving IC's driving power consumption for data signals (Source), but also balances the difference of the RC loading between sub-pixels of the same color in odd and even rows, reducing the risk of display unevenness.

In a second aspect, based on the same inventive concept, in another optional embodiment, a display apparatus is provided, including the display panel provided in the embodiments of the first aspect. The display apparatus may be a display module including the display panel, or a display equipment including the display panel. The display panel may be a conventional organic light-emitting diode (OLED) display panel, a quantum dot light-emitting diode (QD-OLED) display panel, or an M-light-emitting diode (MLED) (including a micro light-emitting diode (Micro-LED) and sub-millimeter light-emitting diode (Mini-LED)) display panel. The display apparatus may be a mobile phone, a tablet computer, a displayer, an in-vehicle display screen, a digital photo frame, a wearable display apparatus such as a virtual reality (VR) device or an augmented reality (AR) device, which is not limited in the embodiments.

Through one or more technical schemes of the present disclosure, the present disclosure has the beneficial effects or advantages as follows.

The present disclosure provides a display panel and a display apparatus, in which a pixel borrowing arrangement is formed with second sub-pixels arranged in the second sub-column by mixing first sub-pixels and third sub-pixels into a column of sub-pixels, that is, part of first sub-pixels and part of third sub-pixels are arranged in the first sub-column, and part of the first sub-pixels and part of the third sub-pixels are arranged in the third sub-column, and a second sub-pixel may borrow the surrounding first sub-pixel and third sub-pixel to form a light-emitting center, which is beneficial to reducing the number of pixels and improving the service life of the display panel. Based on this pixel borrowing arrangement, the conventional driving scheme is that a column of sub-pixels is source-driven through the same data line adjacent thereto. Since sub-pixels of different colors require different driving voltages, there are driving voltage jumps for different pixels in one data line. Whereas, this scheme uses the same data line to drive sub-pixels of the same type, that is, the first sub-pixels are connected to the first data line, the second sub-pixels are connected to the second data line, and the third sub-pixels are connected to the third data line. The driving signals of the first data line and the third data line may be adjusted to stable DC voltage driving, thereby reducing the power consumption loss of the source driving caused by voltage jumps.

Although preferred embodiments of the present disclosure have been described, additional changes and modifications may occur to these embodiments once those skilled in the art understand the basic inventive concepts. Therefore, it is intended that the appended claims be interpreted as including the preferred embodiment and all changes and modifications that fall within the scope of the present disclosure.

It will be apparent that those skilled in the art may make various changes and variations to the present disclosure without departing from the spirit and scope of the present disclosure. That is, these changes and variations of the present disclosure fall within the scope of the claims of the present disclosure and their equivalent technologies, and the present disclosure also encompass them.

What is claimed is:

1. A display panel, comprising:
a base substrate; and
a plurality of pixel units arranged in an array on the base substrate, wherein each of the pixel units includes one first sub-pixel, at least one second sub-pixel and one third sub-pixel; each column of pixel units includes at least a first sub-column, a second sub-column and a third sub-column that are arranged in sequence along a first direction perpendicular to an extension direction of each column of pixel units; in a same column of pixel units, a part of first sub-pixels and a part of third sub-pixels are located in a first sub-column of the same column of pixel units, another part of the first sub-pixels and another part of the third sub-pixels are located in a third sub-column of the same column of pixel units, and at least a part of second sub-pixels are located in a second sub-column of the same column of pixel units; and
a plurality of first data lines, a plurality of second data lines and a plurality of third data lines that are disposed on the base substrate, wherein each column of pixel units corresponds to one of the first data lines, at least one of the second data lines and one of the third data lines; and in the same column of pixel units, the first sub-pixels are electrically connected to one of the first data lines, the second sub-pixels are electrically connected to at least one of the second data lines, and the third sub-pixels are electrically connected to one of the third data lines.

2. The display panel according to claim 1, wherein each of the pixel units includes one first sub-pixel, two second sub-pixels and one third sub-pixel; and each column of pixel units corresponds to one of the first data lines, two of the second data lines, and one of the third data line;
each column of pixel units further includes a fourth sub-column, and in each column of pixel units, the third sub-column is located between the second sub-column and the fourth sub-column; and
in the same column of pixel units, a part of the second sub-pixels are located in the second sub-column and another part of the second sub-pixels are located in the fourth sub-column, second sub-pixels in the second sub-column are electrically connected to one of the two of the second data lines, and second sub-pixels in the fourth sub-column are electrically connected to another of the two of the second data lines; and in the first sub-column and the third sub-column, the first sub-pixels and the third sub-pixels are alternately arranged.

3. The display panel according to claim 2, wherein each sub-pixel includes a first electrode stacked on the base substrate, and the first electrode includes a main body and a conductive block, and:
the display panel further comprises a plurality of first electrode traces, a plurality of second electrode traces and a plurality of third electrode traces that are disposed on the base substrate, wherein
a main body of the first sub-pixel is connected to a conductive block thereof through one of the first electrode traces, and the conductive block is connected to the first data line;
a main body of each of the two second sub-pixels is connected to a conductive block thereof through one of the second electrode traces, and the conductive block is connected to a corresponding second data line; and
a main body of the third sub-pixel is connected to a conductive block thereof through one of the third electrode traces, and the conductive block is connected to the third data line.

4. The display panel according to claim 3, wherein in the same column of pixel units,
for a first sub-pixel proximate to the first data line electrically connected to the same column of pixel units, one end of one of the first electrode traces is connected to a conductive block of the first sub-pixel, and another end is connected to an end of a main body of the first sub-pixel away from the first data line; and
for a first sub-pixel away from the first data line electrically connected to the same column of pixel units, one end of another of the first electrode traces is connected to a conductive block of the first sub-pixel, and another end is connected to an end of a main body of the first sub-pixel proximate to the first data line.

5. The display panel according to claim 3, wherein in the same column of pixel units, for a first sub-pixel proximate to the first data line electrically connected to the same column of pixel units, one of the first electrode traces at least partially surrounds a main body of the first sub-pixel and is connected to a conductive block thereof.

6. The display panel according to claim 3, wherein the main body is in a shape of a rectangle, including a first edge, a second edge, a third edge, and a fourth edge, the first edge and the third edge forming one group of opposite edges, and the second edge and the fourth edge forming another group of opposite edges; and
the first electrode trace includes a first connecting portion, a first connecting line, a second connecting line, and a second connecting portion that are connected to each other, the first connecting portion is connected to the main body, the first connecting line is parallel to the first edge, the second connecting line is parallel to the second edge, and the second connecting portion is connected to the conductive block.

7. The display panel according to claim 3, wherein a deviation between sizes of a first electrode trace of a first sub-pixel proximate to the first data line and a first electrode trace of a first sub-pixel away from the first data line does not exceed 10%, and the deviation between the sizes includes a deviation between lengths of the first electrode traces or a deviation between areas of orthographic projections of the first electrode traces on the base substrate.

8. The display panel according to claim 3, further comprising a source-drain metal layer, wherein the first data lines, the second data lines, and the third data lines are disposed in the source-drain metal layer and extend along a second direction; the source-drain metal layer further includes a plurality of power signal lines extending along the second direction and pads connecting the power signal lines; and the first direction and the second direction intersect, wherein
at least one of the first data line, the second data lines and the third data line passes through a first orthographic projection, and a second orthographic projection at least partially overlaps with a pad; or the first orthographic projection at least partially overlaps with the pad, and at least one of the first data line, the second data lines and the third data line passes through the second orthographic projection; and
the first orthographic projection is orthographic projections of first electrodes of the first sub-pixel and the third sub-pixel on the source-drain metal layer, and the second orthographic projection is an orthographic projection of a first electrode of one of the second sub-pixels on the source-drain metal layer.

9. The display panel according to claim 8, wherein portions, within the first orthographic projection or within the second orthographic projection, of at least two of the first data line, the second data lines and the third data line are distributed symmetrically.

10. The display panel according to claim 8, wherein the source-drain metal layer includes first regions and second regions, the first regions and the second regions are alternately arranged in the first direction, the first data lines, the second data lines, and the third data lines are located in the first regions, and the power signal lines and the pads are located in the second regions; and
in each column of pixel units,
the at least one of the first data line, the second data lines, and the third data line passes through the first orthographic projection, for a first sub-pixel away from the first data line, a first electrode trace of the first sub-pixel crosses adjacent second regions and is connected to a conductive block thereof, and for a first sub-pixel proximate to the first data line, a first electrode trace of the first sub-pixel at least partially surrounds a main body thereof and is connected to a conductive block thereof; or
the first orthographic projection at least partially overlaps with the pad, for a first sub-pixel away from the first data line, a first electrode trace of the first sub-pixel crosses adjacent first regions and is connected to a conductive block thereof, and for a first sub-pixel proximate to the first data line, a first electrode trace of the first sub-pixel at least partially surrounds a main body thereof and is connected to a conductive block thereof.

11. The display panel according to claim 1, wherein the first sub-pixel is a red sub-pixel, the at least one second sub-pixel is a green sub-pixel, and the third sub-pixel is a blue sub-pixel.

12. A display apparatus, comprising the display panel according to claim 1.

13. The display panel according to claim 3, wherein in the same column of pixel units,
for a third sub-pixel proximate to the third data line electrically connected to the same column of pixel units, one end of one of the third electrode traces is connected to a conductive block of the third sub-pixel, and another end is connected to an end of a main body of the third sub-pixel away from the third data line; and
for a third sub-pixel away from the third data line electrically connected to the same column of pixel units, one end of another of the third electrode traces is connected to a conductive block of the third sub-pixel, and another end is connected to an end of a main body of the third sub-pixel proximate to the third data line.

14. The display panel according to claim 3, wherein in the same column of pixel units, for a third sub-pixel proximate to the third data line electrically connected to the same column of pixel units, one of the third electrode traces at least partially surrounds a main body of the third sub-pixel and is connected to a conductive block thereof.

15. display panel according to claim 14, wherein the main body is in a shape of a rectangle, including a first edge, a second edge, a third edge, and a fourth edge, the first edge and the third edge forming one group of opposite edges, and the second edge and the fourth edge forming another group of opposite edges; and
the third electrode trace includes a first connecting portion, a first connecting line, a second connecting line, and a second connecting portion that are connected to each other, the first connecting portion is connected to the main body, the first connecting line is parallel to the first edge, the second connecting line is parallel to the second edge, and the second connecting portion is connected to the conductive block.

16. The display panel according to claim 3, wherein a deviation between sizes of a third electrode trace of a third sub-pixel proximate to the third data line and a third electrode trace of a third sub-pixel away from the third data line does not exceed 10%, and the deviation between the sizes includes a deviation between lengths of the third electrode traces or a deviation between areas of orthographic projections of the third electrode traces on the base substrate.
